(19) United States
(12) Patent Application Publication
(10) Pub. No.: US 2026/0229453 A1
(43) Pub. Date: Aug. 6, 2026

(54) MULTI-CHARGED PARTICLE BEAM WRITING APPARATUS, DATA GENERATION APPARATUS, COMPLEXITY CALCULATION APPARATUS, MULTI-CHARGED PARTICLE BEAM WRITING METHOD AND DATA GENERATION METHOD

(71) Applicant: NuFlare Technology, Inc., Yokohama-shi (JP)

(72) Inventors: Yuko KAJIWARA, Yokohama-shi (JP); Kenichi YASUI, Kawasaki-shi (JP)

(73) Assignee: NuFlare Technology, Inc., Yokohama-shi (JP)

(21) Appl. No.: 19/392,792

(22) Filed: Nov. 18, 2025

(30) Foreign Application Priority Data
Jan. 31, 2025 (JP) 2025-015323

(51) Int. Cl. H01J 37/302; H01J 37/317

(52) U.S. Cl. CPC H01J 37/3023; H01J 37/3177

(57) ABSTRACT

In one embodiment, a multi-charged particle beam writing apparatus includes a writer configured to form a multi-beam composed of a plurality of charged particle beams, individually turn ON/OFF each beam in the multi-beam, and irradiate the charged particle beams onto a target object to write a pattern, and a controller configured to calculate complexity of a figure included in design data, when the complexity does not satisfy a threshold value condition, monotonically divide the figure in a predetermined direction until the complexity satisfies the threshold value condition, and when the complexity satisfies the threshold value condition, generate writing data using the figure satisfying the threshold value condition without dividing the figure, and control the writer based on the writing data.

### CROSS REFERENCE TO RELATED APPLICATION

This application is based upon and claims benefit of priority from the Japanese Patent Application No. 2025-15323, filed on Jan. 31, 2025, the entire contents of which are incorporated herein by reference.

### FIELD

The present invention relates to a multi-charged particle beam writing apparatus, a data generation apparatus, complexity calculation apparatus, a multi-charged particle beam writing method and a data generation method.

### BACKGROUND

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern (mask, or reticle, in particular, when used in a stepper or a scanner) formed on a quartz is employed. The highly precise original image pattern is written by using an electron beam writing apparatus, in which a technology commonly known as electron beam lithography is used.

As an electron beam writing apparatus, for example, a multi-beam writing apparatus is known which emits many beams at one time using a multi-beam to improve its throughput. In the multi-beam writing apparatus, for example, an electron beam emitted from an electron gun passes through an aperture member having a plurality of holes, thus a multi-beam is formed, and blanking control is performed on each beam in a blanking plate. The unblocked beams are reduced in size by an optical system and irradiated onto desired positions on a mask as a writing target.

The storage of the multi-beam writing apparatus stores writing data which is obtained by converting design data (layout data) generated by a designer or the like of semiconductor integrated circuit into a format for the writing apparatus. The multi-beam writing apparatus reads the writing data, performs various types of data processing, and executes writing operation. Among the data processing steps, a so-called rasterization process is performed in which, for example, a writing region of a writing target substrate is virtually divided into a plurality of mesh regions, and for each mesh region, the areal density of a figure pattern disposed in the mesh region is calculated. In addition, the figure pattern defined in the writing data is subdivided, and an irradiation amount correction process is performed based on the dimensions of the subdivided figure.

In a conventional multi-beam writing apparatus, in order to reduce the decrease in the processing speed of such data processing, the writing pattern defined in the writing data is represented by a geometrically simple shape such as a convex polygon. However, when the writing pattern is represented only by a simple figure, a problem arises in that the data volume of the writing data is significantly large, and the storage capacity and the data transfer time increase.

### BRIEF DESCRIPTION OF THE DRAWINGS

FIG. 1 is a schematic view of a multi-charged particle beam writing apparatus according to an embodiment of the present invention.

FIG. 2 is a flowchart for explaining a writing data generation method according to the embodiment.

FIG. 3A illustrates an example of a figure, and FIG. 3B is a view illustrating an example of a convex figure encompassing the figure.

FIGS. 4A and 4B are views illustrating an example in which the length of a curved portion of the figure is represented by the length of a straight line and calculated.

FIGS. 5 is a view illustrating an example in which the length of a curved portion of the figure is represented by the length of a straight line and calculated.

FIGS. 6A and 6B are views illustrating an example of a convex figure encompassing the figure.

FIGS. 7A to 7C are views each illustrating an example of a characteristic length of a convex figure encompassing a figure.

FIGS. 8A and 8B are views each illustrating an example of division of a figure.

FIGS. 9A and 9B are views each illustrating an example of intersection points between a figure and scanning lines.

FIGS. 10A and 10B are views each illustrating an example of intersection points between a figure and scanning lines.

FIG. 11 is a view illustrating an example of intersection points between a figure and scanning lines.

FIG. 12 is a view illustrating an example of intersection points between a figure and scanning lines.

FIG. 13 is a view for explaining the smallest number of monotonous intervals on the outer circumference of a figure.

FIG. 14 is a view for explaining the smallest number of monotonous intervals on the outer circumference of a figure.

FIG. 15 is a view for explaining the smallest number of monotonous intervals on the outer circumference of a figure.

FIG. 16 is a view for explaining the smallest number of monotonous intervals on the outer circumference of a figure.

### DETAILED DESCRIPTION

In one embodiment, a multi-charged particle beam writing apparatus includes a writer configured to form a multi-beam composed of a plurality of charged particle beams, individually turn ON/OFF each beam in the multi-beam, and irradiate the charged particle beams onto a target object to write a pattern, and a controller configured to calculate complexity of a figure included in design data, when the complexity does not satisfy a threshold value condition, monotonically divide the figure in a predetermined direction until the complexity satisfies the threshold value condition, and when the complexity satisfies the threshold value condition, generate writing data using the figure satisfying the threshold value condition without dividing the figure, and control the writer based on the writing data.

Hereinafter, an embodiment of the present invention will be described based on the drawings.

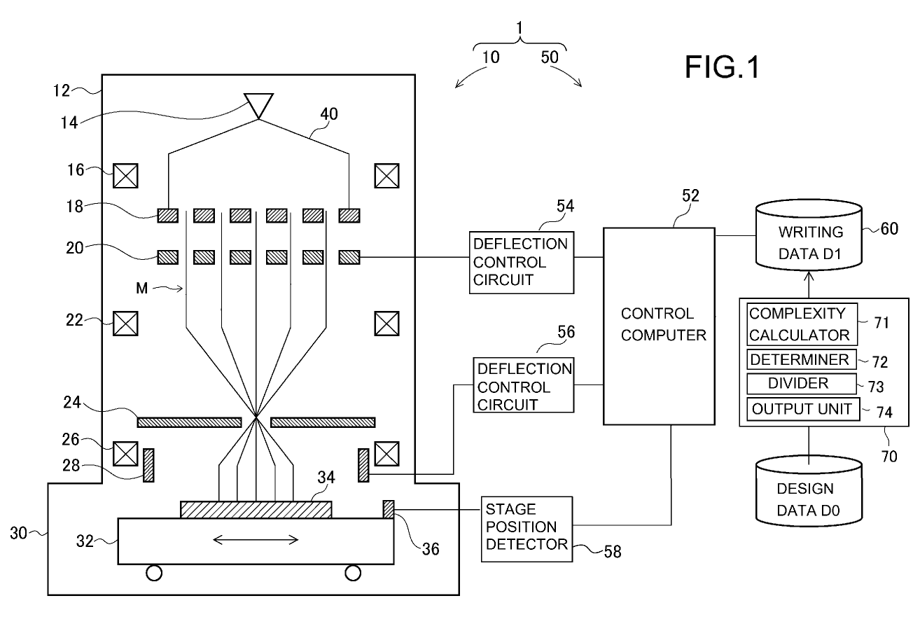

FIG. 1 is a schematic view of a charged particle multi-beam writing apparatus that performs writing using writing data according to the present embodiment. In the present embodiment, the configuration using an electron beam as an example of a charged particle beam will be described. However, the charged particle beam is not limited to an electron beam and may alternatively be another charged particle beam such as an ion beam.

A writing apparatus 1 illustrated in FIG. 1 includes a writer 10 that irradiates a target object such as a mask or a wafer with an electron beam to write a desired pattern; and a controller 50 that controls the writing operation by the writer 10. The writer 10 includes an electron optical column 12 and a writing chamber 30.

In the electron optical column 12, an electron source 14, an illumination lens 16, a shaping aperture array substrate 18, a blanking aperture array substrate 20, a reduction lens 22, a limiting aperture member 24, an objective lens 26, and a deflector 28 are disposed. An XY stage 32 is disposed in the writing chamber 30. A substrate 34 as a writing target is disposed on the XY stage 32. The substrate 34 is e.g., a mask blank. A mirror 36 for measurement of the position of the XY stage 32 is further disposed on the XY stage 32.

The controller 50 includes a control computer 52, deflection control circuits 54 and 56, and a stage position detector 58.

An electron beam 40 emitted from the electron source 14 illuminates the entire shaping aperture array substrate 18 substantially perpendicularly by the illumination lens 16. In the shaping aperture array substrate 18, a plurality of openings are formed in a matrix pattern with a predetermined arrangement pitch. The electron beam 40 illuminates a region including the plurality of openings of the shaping aperture array substrate 18. Respective portions of the electron beam 40 pass through the plurality of openings, thereby forming a multi-beam M as illustrated in FIG. 1.

In the blanking aperture array substrate 20, passage holes are formed corresponding to the arrangement positions of the openings of the shaping aperture array substrate 18, and a blanker consisting of two electrodes forming a pair is disposed at each passage hole. The beams which pass through respective passage holes are each independently deflected by a voltage applied by a blanker. In this manner, a plurality of blankers perform blanking deflection on corresponding beams in the multi-beam which has passed through the plurality of openings of the shaping aperture array substrate 18.

The multi-beam M which has passed through the blanking aperture array substrate 20 is reduced by the reduction lens 22, and travels to the central hole formed in the limiting aperture member 24. The beam deflected by a blanker of the blanking aperture array substrate 20 is displaced from the central hole of the limiting aperture member 24, and is blocked by the limiting aperture member 24. In contrast, the beam not deflected by a blanker of the blanking aperture array substrate 20 passes through the central hole of the limiting aperture member 24.

In this manner, the limiting aperture member 24 blocks the beam which is deflected to achieve a beam-OFF state by a blanker of the blanking aperture array substrate 20. The beam for one shot is formed by the beam which has passed through the limiting aperture member 24 since beam-ON until beam-OFF is achieved. The multi-beam M which has passed through the limiting aperture member 24 is focused by the objective lens 26, and forms a pattern image with a desired reduction ratio. The beams (the entire multi-beam) which have passed through the limiting aperture member 24 are deflected by the deflector 28 in the same direction, and emitted to a desired position on the substrate 34.

When the XY stage 32 is moved continuously, the irradiation position of the beam is controlled by the deflector 28 so that the irradiation position follows the movement of the XY stage 32. The XY stage 32 is moved by a stage controller which is not illustrated, and the position of the XY stage 32 is detected by the stage position detector 58.

The multi-beam emitted at a time is ideally arranged with the pitch which is the product of the arrangement pitch of the plurality of openings of the shaping aperture array substrate 18 and a desired reduction ratio.

The control computer 52 reads writing data D1 from a storage device 60, and performs data conversion processes in multiple stages to generate shot data specific to the apparatus. In the shot data, the irradiation amount of each shot and irradiation position coordinates and the like are defined. For example, the control computer 52 assigns the figure pattern defined in the writing data to corresponding pixels (mesh regions). For each pixel, the control computer 52 calculates the areal density of the figure pattern disposed.

For each pixel, the control computer 52 calculates the irradiation amount of electron beam per shot. For example, an irradiation amount in proportion to the areal density of the pixel is determined, and the irradiation amount is corrected in consideration of dimensional variation due to proximity effect, fogging effect, loading effect and the like.

The control computer 52 outputs the irradiation amount of each shot to the deflection control circuit 54 based on the shot data. The deflection control circuit 54 determines the irradiation time t by dividing the input irradiation amount by the current density. When a corresponding shot is performed, the deflection control circuit 54 applies a deflection voltage to a corresponding blanker of the blanking aperture array substrate 20 so that the blanker is beam-ON for the irradiation time t.

The control computer 52 outputs deflection position data to the deflection control circuit 56 so that each beam is deflected to the position (coordinates) indicated by the shot data. The deflection control circuit 56 calculates a deflection amount, and applies a deflection voltage to the deflector 28. Thus, the multi-beam which has been shot this time is collectively deflected.

When the control computer 52 performs data processing on the writing data D1, quick processing is made possible by representing the writing pattern defined in the writing data D1 by a monotonous figure such as a convex polygon. However, when the writing pattern is represented by a monotonous figure only, the data volume of the writing data is significantly large, and the storage capacity and the data transfer time increase.

Thus, in the present embodiment, an index (complexity) indicating the complexity of the shape of the writing pattern represented by a general figure is calculated, and any figure with complexity not satisfying a threshold value condition is monotonically divided, and any figure with complexity satisfying a threshold value condition is not divided so that writing data is generated from the design data. Here, the general figure includes a straight line, a curve, and is a convex figure or a concave figure.

A complicated shape pattern is monotonically divided and input to the control computer 52, thus data processing can be quickly performed in the control computer 52. A non-complicated shape pattern is represented by a general figure, thus the data volume can be reduced as compared to when all writing patterns are each represented by a monotonous figure only.

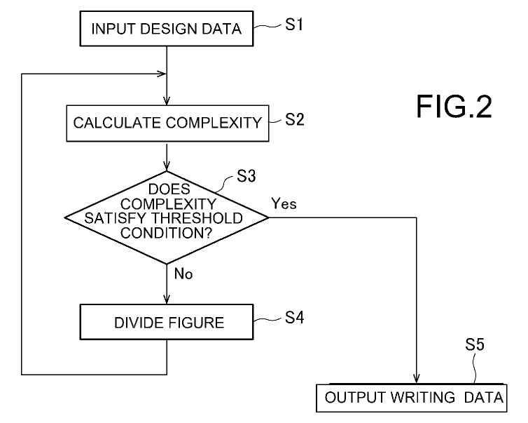

A writing data generation method including calculation of complexity will be described with reference to FIG. 2.

First, the layout of a semiconductor integrated circuit is designed, design data (CAD data) D0 which becomes the layout data is generated, and input to a data generation apparatus 70 (step S1).

The data generation apparatus 70 includes a complexity calculator 71 (a complexity calculation unit), a determiner 72 (a determination unit), a divider 73 (a division unit) and an output unit 74. These functions may be provided by hardware such as an electric circuit, or provided by software. When the functions are provided by software, a program implementing at least part of the functions may be stored in a recording medium, and read and executed by a computer having a CPU. The recording medium that stores the program is not limited to a detachable one such as a magnetic disk or an optical disc, and may be a fixed recording medium such as a hard disk drive or a memory.

The design data D0 includes various figures such as a figure including a straight line and a curve, a convex figure and a concave figure.

The complexity calculator 71 calculates and outputs the complexity that indicates the complexity of the shape of the figure of each writing pattern included in the design data D0 (step S2).

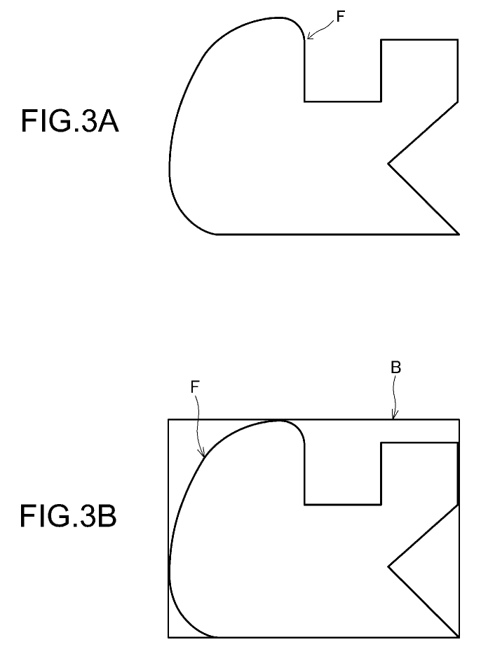

For example, as the complexity, the ratio of the characteristic length of the figure to the characteristic length of a convex figure surrounding (encompassing) the figure is calculated. The characteristic length is, for example, a circumferential length. As the complexity of figure F illustrated in FIG. 3A, the ratio (the circumferential length of the figure F/the circumferential length of bounding box B) of the circumferential length of the figure F to the circumferential length of the bounding box B that surrounds the figure F as illustrated in FIG. 3B can be calculated. The more complicated the shape of the figure F, the greater the value of "the circumferential length of the figure F/the circumferential length of the bounding box B", thus the complexity is increased.

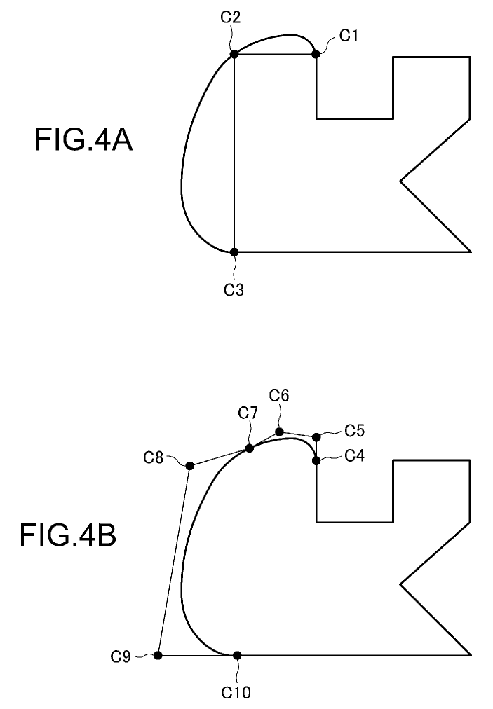

When the figure F includes a curve, instead of the length of the curve, the length of the polyline connecting a plurality of control points of a parametric curve representing the curve may be determined to simplify the calculation of the characteristic length of the figure. FIGS. 4A and 4B illustrate an example of control points when the curve of the figure F is represented by a Bezier curve.

In FIG. 4A, an implicit Bezier is used, and instead of the length of a curved portion, the length of the polyline sequentially connecting control points C1 to C3 is determined. In FIG. 4B, an explicit Bezier is used, and instead of the length of a curved portion, the length of the polyline sequentially connecting control points C4 to C10 is determined.

As the characteristic length of a figure, the circumferential length of a polygon F1 may be determined, which linearly approximates the curved portion (the dashed line portion in FIG. 5) of the figure F as illustrated in FIG. 5. Multiple points are taken on the curve, and the polygon F1 is generated by sequentially connecting the multiple points.

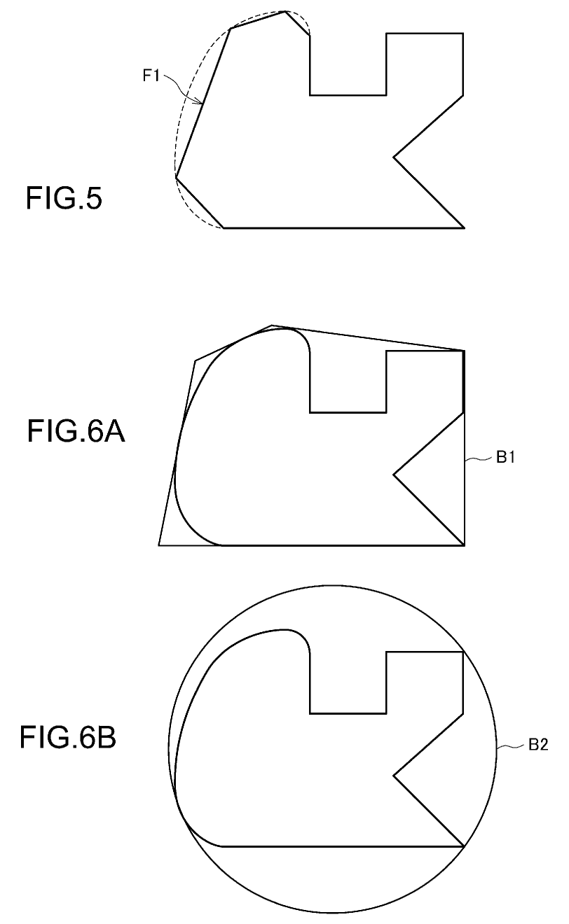

The convex figure encompassing the figure F may be a polygon B1 as illustrated in FIG. 6A (convex closed hull), or a circle B2 as illustrated in FIG. 6B.

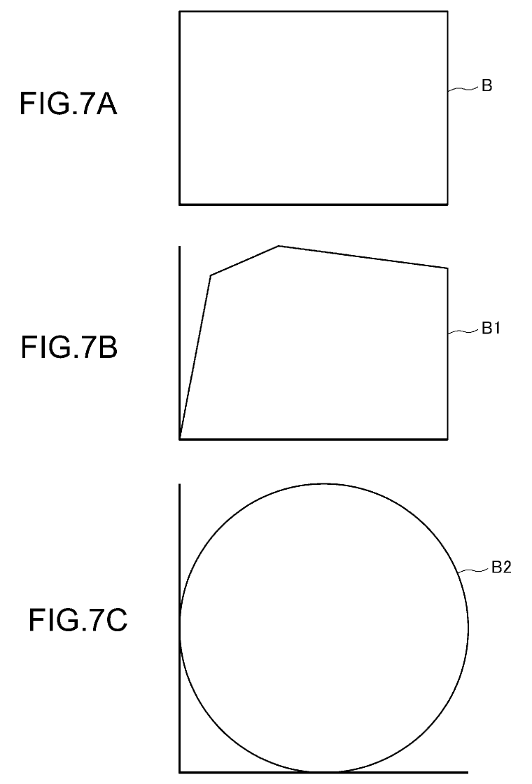

The characteristic length of the convex figure encompassing the figure F may be the circumferential length, or the sum of monotonous intervals in one or more directions indicated by the bold line of FIGS. 7A to 7C. In the example of FIGS. 7A to 7C, the one or more directions are two directions: X direction and Y direction. When the convex figure is a circle, the diameter or radius of the circle may be the characteristic length.

The determiner 72 determines whether the calculated complexity satisfies a predetermined threshold value condition (step S3). For example, when the complexity is "the characteristic length of the figure/the characteristic length of the convex figure surrounding the figure", the determiner 72 determines that, when the complexity is less than or equal to a predetermined threshold value, the threshold value condition is met, and when the complexity is greater than a predetermined threshold value, the threshold value condition is not met.

The divider 73 divides the figure determined not to meet the threshold value condition, in other words, the figure in a complicated shape (step S4). The divider 73 monotonically divides the figure in a predetermined direction.

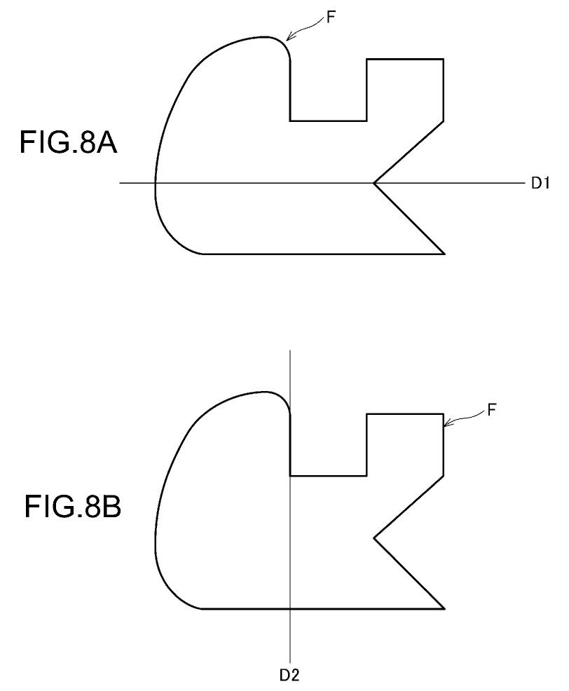

The method of dividing a figure is not limited, and for example, a figure is divided by a dividing line passing through at least one of multiple vertices of the figure. FIG. 8A illustrates an example of division of the figure F by a dividing line D1 extending in X direction. FIG. 8B illustrates an example of division of the figure F by a dividing line D2 extending in Y direction.

Division of the figure and calculation of the complexity are repeatedly performed until the complexity satisfies the threshold value condition. First, monotonous division in a predetermined direction is repeated, and when the divided figure does not satisfy the threshold value condition, monotonous division in another direction is made. When the figure monotonically divided in all directions does not satisfy the threshold value condition, the figure is divided to be a convex figure.

The output unit 74 generates and outputs the writing data D1 that defines figures with complexity satisfying the threshold value condition (step S5). The writing data D1 is stored in the storage device 60. For example, in the writing data, the position of each vertex is sequentially represented by the displacement from the adjacent vertex located around the figure from the origin of the figure. When the figure includes a curve, the positions of multiple control points of a parametric curve representing the curve are each represented by the displacement from the adjacent control point or vertex.

The control computer 52 reads the writing data D1, reconstructs the figure, and performs data conversion processes in multiple stages.

The complexity that indicates the complexity of the shape of a figure in the writing pattern is not limited to the ratio of the characteristic length of the figure to the characteristic length of a convex figure surrounding the figure, and various indices may be used.

For example, the number of intersection points between a plurality of scanning lines extending in a predetermined direction with an interval and the contour (outer circumference) of the figure may be used as the complexity. In this case, when the number of intersection points is greater than or equal to a predetermined value, it is determined that the threshold value condition is not met, and when the number of intersection points is less than a predetermined value, it is determined that the threshold value condition is met.

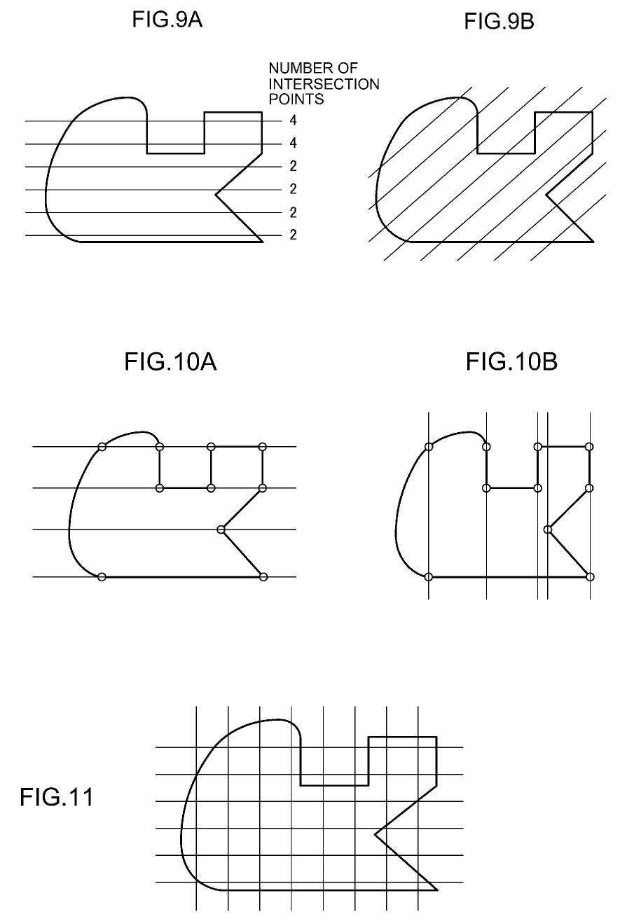

The scanning lines may be equally spaced as illustrated in FIGS. 9A and 9B, or may pass through a vertex of the figure as illustrated in FIGS. 10A and 10B. FIG. 9A illustrates the number of intersection points of each scanning line.

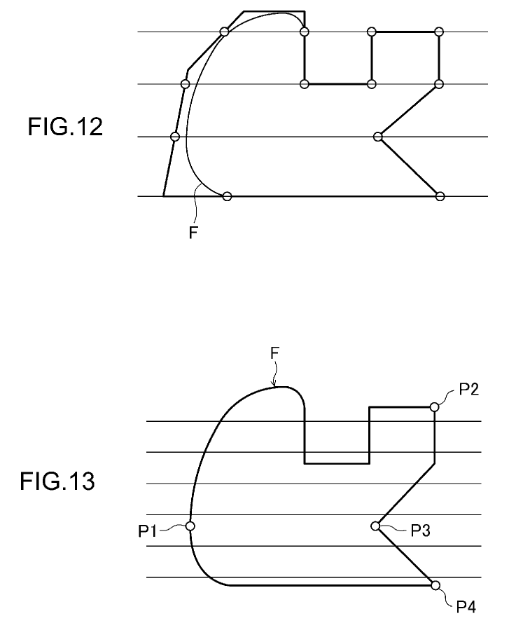

As illustrated in FIG. 11, the number of intersection points between the scanning lines in two perpendicular directions and the contour of the figure may be used as the complexity.

As illustrated in FIG. 12, the curve portion of the figure F may be changed to the polyline connecting a plurality of control points of a parametric curve representing the curve, and the number of intersection points of scanning lines may be determined.

The intersection point density that is the number of intersection points per unit area may be used as the complexity.

The smallest number of monotonous intervals in one or more predetermined directions of the figure contour (outer circumference) may be used as the complexity. When the smallest number of monotonous intervals is greater than or equal to a predetermined value, it is determined that the threshold value condition is not met, and when the smallest number of monotonous intervals is less than a predetermined value, it is determined that the threshold value condition is met.

As illustrated in FIG. 13, the contour of the figure F has no portion facing in -X direction on the contour part from point P1 to point P2 clockwise, thus the contour part is a monotonous interval in X direction. The contour part from point P2 to point P3 has no portion facing in +X direction, thus is a monotonous interval in X direction. The contour part from point P3 to point P4 monotonically faces in +X direction, thus is a monotonous interval in X direction. The contour part from point P4 to point P1 monotonically faces in -X direction, thus is a monotonous interval in X direction. Thus, the smallest number of monotonous intervals in X direction on the contour of the figure F is 4.

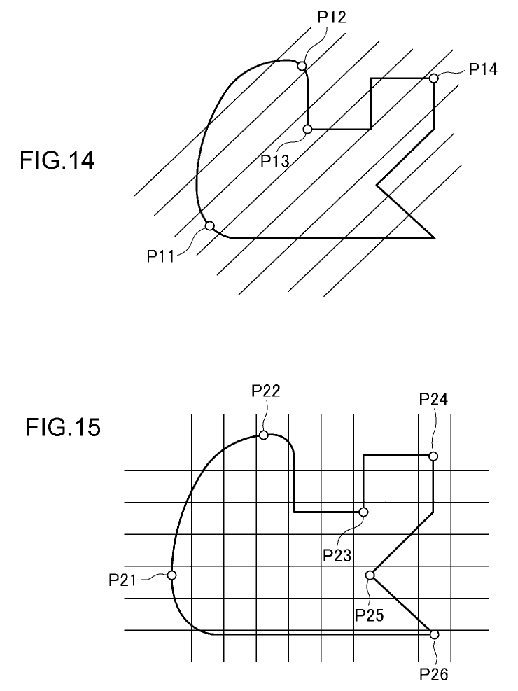

In the diagonal direction illustrated in FIG. 14, the interval from point P11 to point P12, the interval from point P12 to point P13, the interval from point P13 to point P14, and the interval from point P14 to point P11 are each monotonous interval, thus the smallest number of monotonous intervals is 4.

In the two directions of X direction and Y direction illustrated in FIG. 15, the interval from point P21 to point P22, the interval from point P22 to point P23, the interval from point P23 to point P24, the interval from point P24 to point P25, the interval from point P25 to point P26, the interval from point P26 to point P21 are each monotonous interval, thus the smallest number of monotonous intervals is 6.

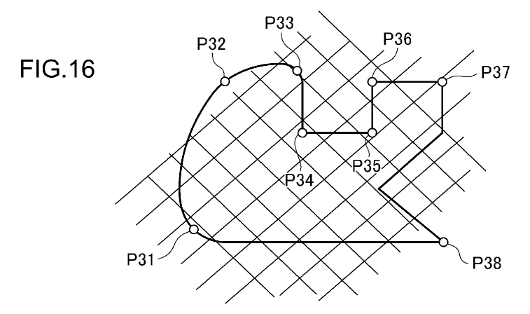

In the two diagonal directions illustrated in FIG. 16, the interval from point P31 to point P32, the interval from point P32 to point P33, the interval from point P33 to point P34, the interval from point P34 to point P35, the interval from point P35 to point P36, the interval from point P36 to point P37, the interval from point P37 to point P38, the interval from point P38 to point P31 are each monotonous interval, thus the smallest number of monotonous intervals is 8.

In the above embodiment, for a FIGURE(monotonous figure and convex figure) in a specific shape allowing quick data processing by the control computer 52, even if the figure does not meet the threshold value condition, writing data may be generated without dividing the figure, and may be input to the control computer 52.

The process of generating the writing data D1 according to the embodiment may be performed in the control computer 52 of the writing apparatus 1. In other words, the control computer 52 may have the function of the data generation apparatus 70.

Note that the present invention may be applied to an inspection device. For example, when an image of a mask pattern is generated from a database for die-to-database inspection by an inspection device, the present invention may be applied.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam writing apparatus comprising:
a writer configured to form a multi-beam composed of a plurality of charged particle beams, individually turn ON/OFF each beam in the multi-beam, and irradiate the charged particle beams onto a target object to write a pattern; and
a controller configured to calculate complexity of a figure included in design data,
when the complexity does not satisfy a threshold value condition, monotonically divide the figure in a predetermined direction until the complexity satisfies the threshold value condition, and
when the complexity satisfies the threshold value condition, generate writing data using the figure satisfying the threshold value condition without dividing the figure, and
control the writer based on the writing data.

2. The multi-charged particle beam writing apparatus according to claim 1,
wherein the complexity is a ratio of a characteristic length of the figure to a characteristic length of a convex figure encompassing the figure, a number of intersection points between a plurality of scanning lines extending in a predetermined direction and the figure, or a minimum number of monotonous intervals in a predetermined direction on an outer circumference of the figure.

3. The multi-charged particle beam writing apparatus according to claim 1,
wherein the controller repeatedly performs division of the figure and calculation of the complexity of the divided figure until the complexity of the divided figure satisfies the threshold value condition.

4. A data generation apparatus for generating writing data used by a multi-charged particle beam writing apparatus, the data generation apparatus comprising:
a complexity calculator configured to calculate complexity of a figure included in design data;
a determiner configured to determine whether the complexity satisfies a threshold value condition;
a divider configured, when the complexity satisfies the threshold value condition, to not divide the figure, and when the complexity does not satisfy the threshold value condition, to monotonically divide the figure in a predetermined direction until the complexity satisfies the threshold value condition; and
an output unit configured to generate and output the writing data using the figure satisfying the threshold value condition.

5. The data generation apparatus according to claim 4,
wherein the complexity is a ratio of a characteristic length of the figure to a characteristic length of a convex figure encompassing the figure, a number of intersection points between a plurality of scanning lines extending in a predetermined direction and the figure, or a minimum number of monotonous intervals in a predetermined direction on an outer circumference of the figure.

6. The data generation apparatus according to claim 4,
wherein division of the figure by the divider and calculation of the complexity of the divided figure by the complexity calculator are repeatedly performed until the complexity of the divided figure satisfies the threshold value condition.

7. A complexity calculation apparatus that calculates and outputs, as complexity of a figure included in design data, a ratio of a characteristic length of the figure to a characteristic length of a convex figure encompassing the figure, a number of intersection points between a plurality of scanning lines extending in a predetermined direction and the figure, or a minimum number of monotonous intervals in a predetermined direction on an outer circumference of the figure.

8. A multi-charged particle beam writing method comprising:
calculating complexity of a figure included in design data;
when the complexity satisfies the threshold value condition, not dividing the figure, and when the complexity does not satisfy the threshold value condition, monotonically dividing the figure in a predetermined direction until the complexity satisfies the threshold value condition, and generating writing data using the figure satisfying the threshold value condition; and
forming a multi-beam composed of a plurality of charged particle beams, controlling, based on the writing data, a writer that individually turns ON/OFF a corresponding one of beams in the multi-beam, and irradiating the charged particle beams onto a target object to write a pattern.

9. A data generation method for generating writing data used by a multi-charged particle beam writing apparatus, the data generation method comprising:
calculating complexity of a figure included in design data;
determining whether the complexity satisfies a threshold value condition;
when the complexity satisfies the threshold value condition, not dividing the figure, and when the complexity does not satisfy the threshold value condition, monotonically dividing the figure in a predetermined direction until the complexity satisfies the threshold value condition; and
generating the writing data using the figure satisfying the threshold value condition.
